(19) United States
(12) Patent Application Publication
(10) Pub. No.: US 2025/0226294 A1
(43) Pub. Date: Jul. 10, 2025

(54) SEMICONDUCTOR MODULE

(71) Applicant: FUJI ELECTRIC CO., LTD., Kawasaki-shi (JP)

(72) Inventors: Makoto ISOZAKI, Matsumoto-city (JP); Hiroaki ICHIKAWA, Matsumoto-city (JP)

(73) Assignee: FUJI ELECTRIC CO., LTD., Kawasaki-shi (JP)

(21) Appl. No.: 19/091,643

(22) Filed: Mar. 26, 2025

Related U.S. Application Data
(63) Continuation of application No. PCT/JP2024/008000, filed on Mar. 4, 2024.

(30) Foreign Application Priority Data
Apr. 12, 2023 (JP) 2023-064757

(51) Int. Cl. H01L 23/495; H01L 25/07; H05K 1/14; H05K 1/18

(52) U.S. Cl. CPC H01L 23/49565; H01L 25/072; H05K 1/142; H05K 1/181; H05K 2201/10166

(57) ABSTRACT

A semiconductor module, including: a terminal case having first and second input terminals disposed at a first short side portion, an output terminal disposed at a second short side portion, a first control terminal and a first auxiliary terminal disposed at a first long side portion, and a second control terminal and a second auxiliary terminal disposed at a second long side portion; a first insulated circuit substrate having a plurality of first switching elements, and first to third metal patterns; a second insulated circuit substrate having a plurality of second switching elements and fourth to seventh metal patterns; and a first wiring member, having two end connected respectively to the fifth metal pattern at a position that is farther, in the direction of the first long side portion, from the first short side portion than a midpoint of the second insulated circuit substrate, and to the second auxiliary terminal.

### CROSS-REFERENCE TO RELATED APPLICATION

This application is a continuation application of International Application PCT/JP2024/008000 filed on Mar. 4, 2024, which designated the U.S., which claims priority to Japanese Patent Application No. 2023-064757, filed on Apr. 12, 2023, the entire contents of which are incorporated herein by reference.

### BACKGROUND OF THE INVENTION

### 1. Field of the Invention

The embodiments discussed herein relate to a semiconductor module.

### 2. Background of the Related Art

Some semiconductor modules that are used in power conversion devices and others each include a gate terminal and an auxiliary terminal (for example, sense emitter terminal, source or drain terminal, etc.) for connection to a drive circuit that drives a switching element (see, for example, International Publication Pamphlet No. WO 2015/076257 and Japanese Laid-open Patent Publication No. 2004-22960).

### SUMMARY OF THE INVENTION

According to an aspect, there is provided a semiconductor module, including: a terminal case, having: four side portions, which include a first short side portion and a second short side portion opposite to each other and extending in a first direction, and a first long side portion and a second long side portion opposite to each other and extending in a second direction, the four side portions surrounding a region, a first input terminal and a second input terminal disposed at the first short side portion, an output terminal disposed at the second short side portion, a first control terminal and a first auxiliary terminal disposed at the first long side portion, and a second control terminal and a second auxiliary terminal disposed at the second long side portion; a first insulated circuit substrate disposed adjacent to the second short side portion in the region surrounded by the four side portions of the terminal case, the first insulated circuit substrate having, on a front surface thereof, a plurality of first switching elements each including a first input electrode, a first output electrode, and a first control electrode, a first metal pattern electrically connected to the first input terminal and the first input electrodes, a second metal pattern electrically connected to the output terminal, the first output electrodes, and the first auxiliary terminal, and a third metal pattern electrically connected to the first control electrodes and the first control terminal; a second insulated circuit substrate disposed adjacent to the first short side portion in the region surrounded by the four side portions of the terminal case, the second insulated circuit substrate having, on a front surface thereof, a plurality of second switching elements each including a second input electrode, a second output electrode, and a second control electrode, a fourth metal pattern electrically connected to the first input terminal and the first metal pattern, a fifth metal pattern electrically connected to the second input terminal, the second output electrodes, and the second auxiliary terminal, the fifth metal pattern extending in the second direction, a sixth metal pattern electrically connected to the second input electrodes and the second metal pattern, and a seventh metal pattern electrically connected to the second control electrodes and the second control terminal; and a first wiring member, having: a first end connected to the fifth metal pattern at a position that is farther in the second direction from the first short side portion than a midpoint of the second insulated circuit substrate with respect to the second direction, and a second end connected to the second auxiliary terminal.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view illustrating an example of a semiconductor module according to a first embodiment;

FIG. 2 is a circuit diagram for describing turn-on loss that occurs in the case where a gate wire length is short;

FIG. 3 is a circuit diagram for describing turn-on loss that occurs in the case where the gate wire length is long;

FIG. 4 illustrates changes over time in the current and voltage at various locations in a semiconductor module of a first comparison example in the case where a gate wire length is short;

FIG. 5 illustrates changes over time in the current and voltage at the various locations in the semiconductor module of the first comparison example in the case where the gate wire length is long;

FIG. 6 is a circuit diagram illustrating an example of leading out a second auxiliary terminal in the semiconductor module according to the first embodiment;

FIGS. 7A and 7B include views each representing changes over time in the current and voltage at various locations in the semiconductor module in the case where the second auxiliary terminal is led out from a position that is closer to a first short side portion than the midpoint of the length of a second insulated circuit substrate in the long-side direction of a terminal case;

FIGS. 8A and 8B include views each representing changes over time in the current and voltage at the various locations in the semiconductor module in the case where the second auxiliary terminal is led out from a position that is farther from the first short side portion than the midpoint of the length of the second insulated circuit substrate in the long-side direction of the terminal case;

FIG. 9 is a plan view illustrating an example of a semiconductor module according to a second embodiment;

FIG. 10 is a circuit diagram of the semiconductor module according to the second embodiment;

FIG. 11 is a plan view of a semiconductor module according to a first modification of the second embodiment; and

FIG. 12 is a plan view of a semiconductor module according to a second modification of the second embodiment.

### DETAILED DESCRIPTION OF THE INVENTION

Hereinafter, embodiments will be described with

reference to the accompanying drawings.

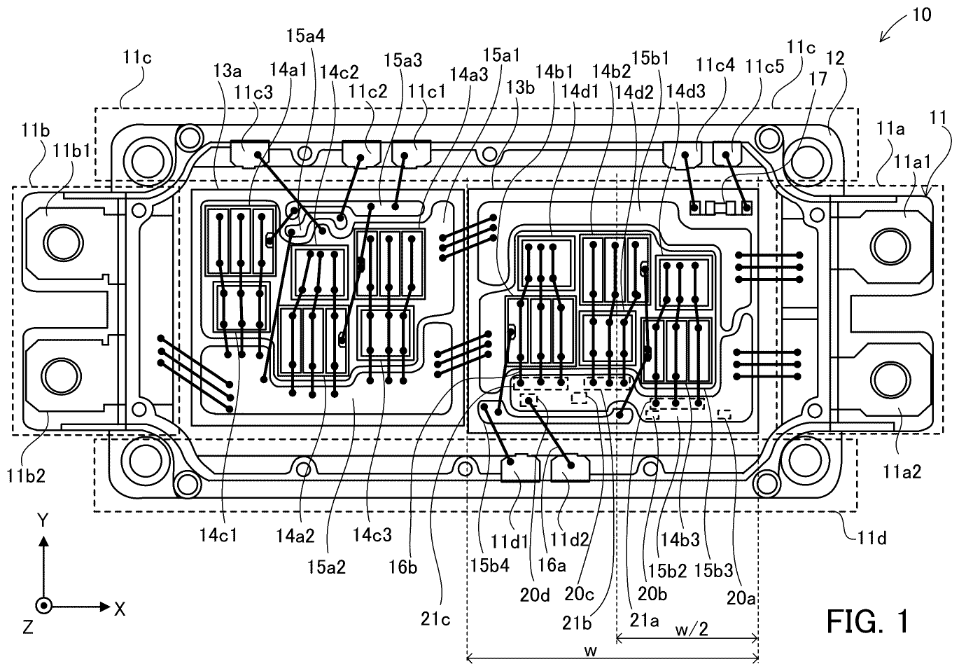

In the following description, the terms “front surface” and “top surface” refer to an X-Y plane facing upward (the +Z direction) in a semiconductor module 10 of FIG. 1, etc. Similarly, the term “up” refers to the upward direction (the +Z direction) in the semiconductor module 10 of FIG. 1, etc. The terms “rear surface” and “bottom surface” refer to an X-Y plane facing downward (the −Z direction) in the semiconductor module 10 of FIG. 1, etc. Similarly, the term “down” refers to the downward direction (the −Z direction) in the semiconductor module 10 of FIG. 1, etc. The same directionality applies to other drawings as appropriate. The terms “front surface,” “top surface,” “up,” “rear surface,” “bottom surface,” “down,” and “side surface” are used for convenience to describe relative positional relationships, and do not limit the technical concept of the embodiments. For example, the terms “up” and “down” are not always related to the vertical directions to the ground. That is, the “up” and “down” directions are not limited to those related to the gravity direction.

### First Embodiment

FIG. 1 is a plan view illustrating an example of a semiconductor module according to a first embodiment.

The semiconductor module 10 includes a terminal case 11, a metal base 12, a first insulated circuit substrate 13a, and a second insulated circuit substrate 13b.

Th terminal case 11 has a first short side portion 11a, a second short side portion 11b opposite to the first short side portion 11a, a first long side portion 11c, and a second long side portion 11d opposite to the first long side portion 11c. A first input terminal 11a1 and a second input terminal 11a2 are disposed at the first short side portion 11a. The first input terminal 11a1 and the second input terminal 11a2 are external connection terminals for main current, to which different potentials are applied. The following description assumes that the positive terminal of a direct current power supply is connected to the first input terminal 11a1 and the negative terminal of the direct current power supply is connected to the second input terminal 11a2.

Output terminals 11b1 and 11b2 are disposed at the second short side portion 11b. A first control terminal 11c1 and a first auxiliary terminal 11c2 are disposed at the first long side portion 11c, and a second control terminal 11d1 and a second auxiliary terminal 11d2 are disposed at the second long side portion 11d. The first auxiliary terminal 11c2 and second auxiliary terminal 11d2 each may be called a sense emitter terminal, an auxiliary emitter terminal, a sense source terminal, an auxiliary source terminal, or another. Referring to the example of FIG. 1, a third auxiliary terminal 11c3 and temperature detection terminals 11c4 and 11c5 are further disposed at the first long side portion 11c, but these terminals do not need to be provided. The third auxiliary terminal 11c3 may be called a sense collector terminal, a sense drain terminal, or another.

The above terminals are made of a material with high electrical conductivity. Examples of the material here include aluminum, iron, silver, copper, or an alloy containing at least one of these. The above terminals provided in the terminal case 11 are integrally formed with its frame-shaped body.

The above-described terminal case 11 is disposed on the metal base 12. The metal base 12 is used for heat dissipation of the semiconductor module 10, and is made of a metal with high thermal conductivity as a main component. Examples of the metal here include copper, aluminum, and an alloy containing at least one of these. The metal base 12 may be plated to improve its corrosion resistance. Examples of the plating material used here include nickel, a nickel-phosphorus alloy, and a nickel-boron alloy.

The first insulated circuit substrate 13a is disposed adjacent to the second short side portion 11b in the region surrounded by the terminal case 11 on the metal base 12. The second insulated circuit substrate 13b is disposed adjacent to the first short side portion 11a in the region surrounded by the terminal case 11 on the metal base 12. The first insulated circuit substrate 13a and second insulated circuit substrate 13b are made of ceramics with good thermal conductivity. The ceramics here is a material with high thermal conductivity, such as aluminum oxide, aluminum nitride, or silicon nitride. For example, the first insulated circuit substrate 13a and second insulated circuit substrate 13b are fixed to the metal base 12 using a solder.

The first insulated circuit substrate 13a has a plurality of first switching elements 14a1 to 14a3, a first metal pattern 15a1, a second metal pattern 15a2, and a third metal pattern 15a3 provided on the front surface thereof. The second insulated circuit substrate 13b has a plurality of second switching elements 14b1 to 14b3, a fourth metal pattern 15b1, a fifth metal pattern 15b2, a sixth metal pattern 15b3, and a seventh metal pattern 15b4 provided on the front surface thereof.

The first switching elements 14a1 to 14a3 and second switching elements 14b1 to 14b3 are power metal-oxide-semiconductor field-effect transistors (MOSFETs), insulated gate bipolar transistors (IGBTs), or others, for example. The first switching elements 14a1 to 14a3 function as switching elements of an upper arm, whereas the second switching elements 14b1 to 14b3 function as switching elements of a lower arm.

Referring to the example of FIG. 1, three first switching elements 14a1 to 14a3 are arranged in the long-side direction (X direction) of the terminal case 11 on the front surface of the first insulated circuit substrate 13a. In addition, three second switching elements 14b1 to 14b3 are arranged in the X direction on the front surface of the second insulated circuit substrate 13b.

In this connection, the number of switching elements for the upper arm and the number of switching elements for the lower arm are each not limited to three.

Each first switching element 14a1 to 14a3 includes a first input electrode, a first output electrode, and a first control electrode. Each second switching element 14b1 to 14b3 includes a second input electrode, a second output electrode, and a second control electrode.

In the case where each of these switching elements is an n-channel power MOSFET, the corresponding first input electrode or second input electrode is a drain electrode provided on the rear surface of the switching element. The corresponding first output electrode or second output electrode is a source electrode provided on the front surface of the switching element. The corresponding first control electrode or second control electrode is a gate electrode provided on the front surface of the switching element.

In the case where each of the switching elements is an IGBT, the corresponding first input electrode or second input electrode is a collector electrode provided on the rear surface of the switching element. The corresponding first output electrode or second output electrode is an emitter electrode provided on the front surface of the switching element. The corresponding first control electrode or second control electrode is a gate electrode provided on the front surface of the switching element.

In this connection, these switching elements may be power MOSFETs made of silicon carbide, or others.

The following description assumes that the first switching elements 14a1 to 14a3 and second switching elements 14b1 to 14b3 are IGBTs. Therefore, the first input electrodes and second input electrodes are referred to as collector electrodes, the first output electrodes and second output electrodes are referred to as emitter electrodes, and the first control electrodes and second control electrodes are referred to as gate electrodes.

The first metal pattern 15a1 is electrically connected to the first input terminal 11a1 and the collector electrodes of the first switching elements 14a1 to 14a3. The collector electrodes on the rear surfaces of the first switching elements 14a1 to 14a3 are bonded to the first metal pattern 15a1 using a solder, for example. In this connection, referring to the example of FIG. 1, the first metal pattern 15a1 is further electrically connected to the third auxiliary terminal 11c3.

The second metal pattern 15a2 extends in the long-side direction (X direction) of the terminal case 11, and is electrically connected to the output terminals 11b1 and 11b2, the emitter electrodes of the first switching elements 14a1 to 14a3, and the first auxiliary terminal 11c2.

The third metal pattern 15a3 is electrically connected to the gate electrodes of the first switching elements 14a1 to 14a3 and the first control terminal 11c1.

The fourth metal pattern 15b1 is electrically connected to the first input terminal 11a1 and the first metal pattern 15a1.

The fifth metal pattern 15b2 extends in the long-side direction (X direction) of the terminal case 11, and is electrically connected to the second input terminal 11a2, the emitter electrodes of the second switching elements 14b1 to 14b3, and the second auxiliary terminal 11d2.

The sixth metal pattern 15b3 is electrically connected to the collector electrodes of the second switching elements 14b1 to 14b3 and the second metal pattern 15a2. The collector electrodes on the rear surfaces of the second switching elements 14b1 to 14b3 are bonded to the sixth metal pattern 15b3 using a solder, for example.

The seventh metal pattern 15b4 is electrically connected to the gate electrodes of the second switching elements 14b1 to 14b3 and the second control terminal 11d1.

The electrical connections between the emitter electrodes of the switching elements, the metal patterns, and the terminals are achieved using wiring members (for example, a first wiring member 16a, second wiring members 16b, and others) indicated by a black thick line in FIG. 1. Bonding wires, lead frames, and others may be used as the wiring members.

For example, the fifth metal pattern 15b2 has three connection areas 21a to 21c arranged in the X direction, to which the three emitter electrodes of the second switching elements 14b1 to 14b3 are electrically connected via wiring members (the second wiring members 16b, or others), respectively.

The above-described metal patterns are made of a metal with high electrical conductivity. The metal here is copper, a copper alloy, or the like. As each of the first insulated circuit substrate 13a and second insulated circuit substrate 13b that include the above metal patterns, a direct copper bonding (DCB) substrate or an active metal brazed (AMB) substrate may be used, for example.

As illustrated in FIG. 1, diodes 14c1, 14c2, and 14c3 are further provided on the first insulated circuit substrate 13a. Likewise, diodes 14d1, 14d2, and 14d3 are further provided on the second insulated circuit substrate 13b. Each of these diodes is a Schottky barrier diode (SBD), a P-intrinsic-N (PiN) diode, or another, and is connected as a free-wheeling diode (FWD) in inverse parallel to a switching element. Each of the diodes has an output electrode (cathode electrode) as a main electrode on the rear surface thereof, and an input electrode (anode electrode) as a main electrode on the front surface thereof.

The output electrodes on the rear surfaces of the diodes 14c1 to 14c3 are bonded to the front surface of the first metal pattern 15a1 using a solder. The output electrodes on the rear surfaces of the diodes 14d1 to 14d3 are bonded to the front surface of the sixth metal pattern 15b3 using a solder. The input electrodes on the front surfaces of the diodes 14c1 to 14c3 are each electrically connected to the emitter electrode on the front surface of one of the first switching elements 14a1 to 14a3 and the second metal pattern 15a2 with wiring members such as bonding wires. The input electrodes on the front surfaces of the diodes 14d1 to 14d3 are each electrically connected to the emitter electrode on the front surface of any one of the second switching elements 14b1 to 14b3 and the fifth metal pattern 15b2 with wiring members such as bonding wires.

Furthermore, referring to the example of FIG. 1, an eighth metal pattern 15a4 is further provided on the first insulated circuit substrate 13a. The eighth metal pattern 15a4 is electrically connected to the second metal pattern 15a2 via a wiring member and to the first auxiliary terminal 11c2 via a wiring member.

Still further, referring to the example of FIG. 1, a thermistor 17 that is electrically connected to the temperature detection terminals 11c4 and 11c5 is provided on the second insulated circuit substrate 13b.

Although not illustrated, the semiconductor module 10 further includes a sealing material filling the housing region surrounded by the terminal case 11 and a lid sealing the inside of the terminal case 11.

In the semiconductor module 10 configured as above, the first wiring member 16a electrically connecting the second auxiliary terminal 11d2 to the fifth metal pattern 15b2 has the following connection configuration.

One end of the first wiring member 16a is connected to a position (a position 20d in the example of FIG. 1) on the fifth metal pattern 15b2 that is farther from the first short side portion 11a than the midpoint (w/2) of the length w of the second insulated circuit substrate 13b in the long-side direction (X direction) of the terminal case 11. The other end of the first wiring member 16a is connected to the second auxiliary terminal 11d2.

The following describes the reason and effect of connecting the first wiring member 16a in this manner.

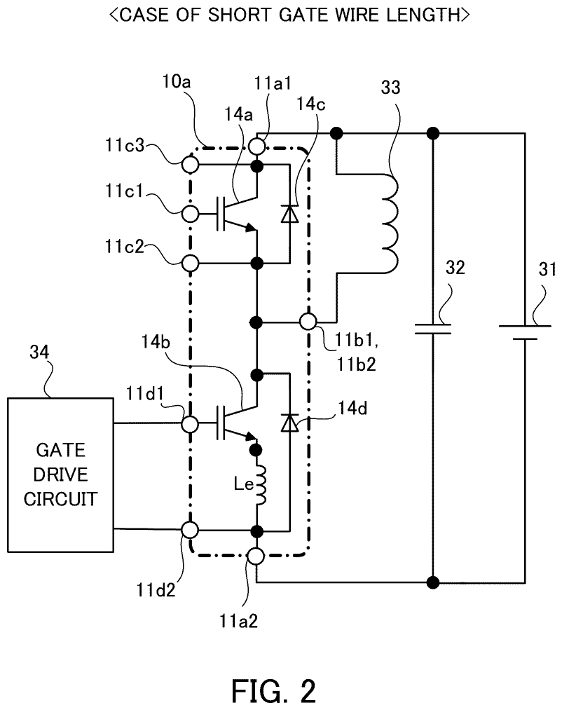

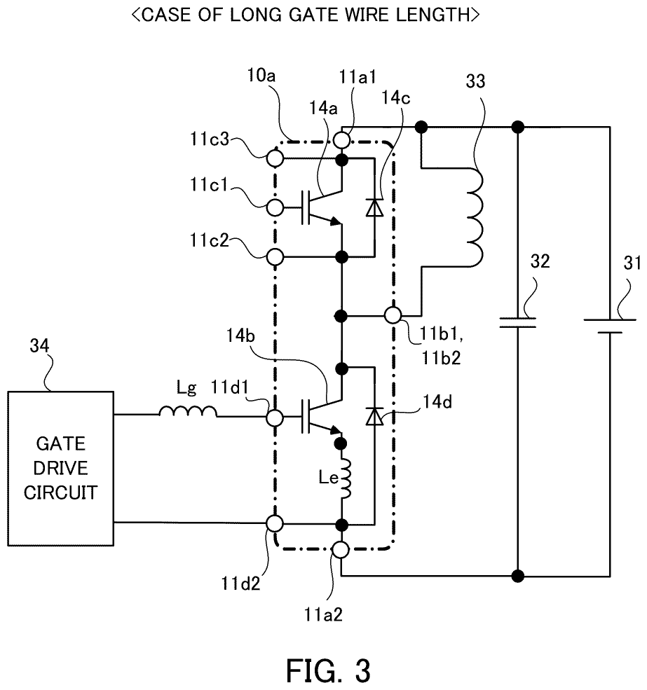

FIG. 2 is a circuit diagram for describing turn-on loss that occurs in the case where a gate wire length is short. FIG. 3 is a circuit diagram for describing turn-on loss that occurs in the case where the gate wire length is long. In FIGS. 2 and 3, the same reference numerals are given to the same components as in the semiconductor module 10 of FIG. 1. FIGS. 2 and 3 are each an equivalent circuit of a semiconductor module in which one end of the first wiring member 16a is connected to a position 20a on the fifth metal pattern 15b2 that is closer to the first short side portion 11a than the midpoint of the length w of the second insulated circuit substrate 13b in the X direction in FIG. 1. The semiconductor module in FIGS. 2 and 3 is given the reference numeral 10a, in order to distinguish from the semiconductor module 10 of FIG. 1. Hereinafter, this semiconductor module 10a may be referred to as a semiconductor module of a first comparison example.

FIGS. 2 and 3 illustrate a first switching element 14a corresponding to the three first switching elements 14a1 to 14a3 of FIG. 1 and a second switching element 14b corresponding to the three second switching elements 14b1 to 14b3 of FIG. 1. In addition, FIGS. 2 and 3 illustrate a diode 14c corresponding to the three diodes 14c1 to 14c3 of FIG. 1 and a diode 14d corresponding to the three diodes 14d1 to 14d3 of FIG. 1.

A direct current power supply 31 and a capacitor 32 are connected between a first input terminal 11a1 and a second input terminal 11a2, and a load 33 is connected between the first input terminal 11a1 and each output terminal 11b1 and 11b2.

A gate drive circuit 34 is connected to a second control terminal 11d1 and a second auxiliary terminal 11d2. Although not illustrated, another gate drive circuit is connected to a first control terminal 11c1 and a first auxiliary terminal 11c2.

There is a possibility that turn-on loss increases in the case where the length of a gate wire connecting the gate electrode of the second switching element 14b to the gate drive circuit 34 is short.

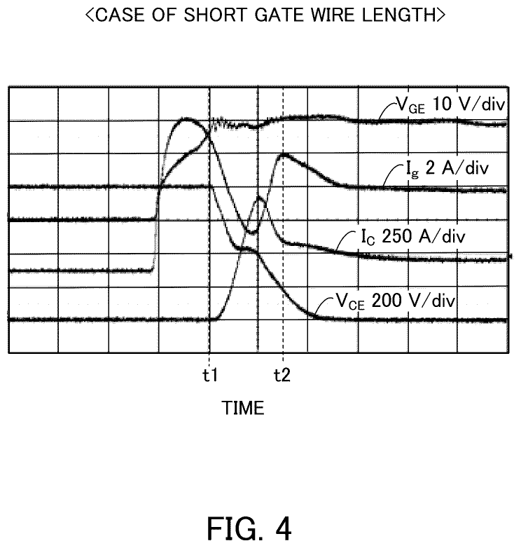

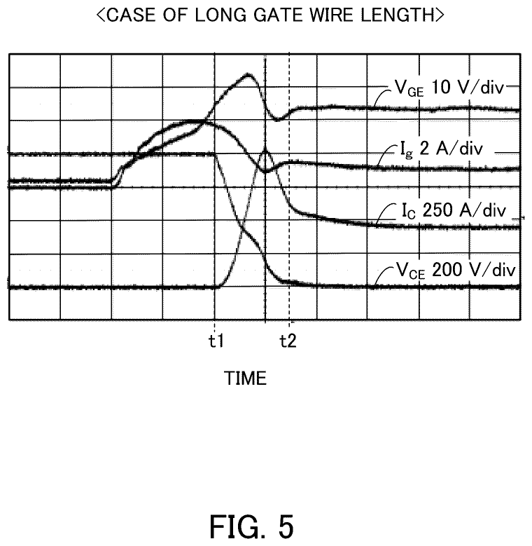

FIG. 4 illustrates changes over time in the current and voltage at various locations in the semiconductor module of the first comparison example in the case where the gate wire length is short. FIG. 5 illustrates changes over time in the current and voltage at the various locations in the semiconductor module of the first comparison example in the case where the gate wire length is long. In FIGS. 4 and 5, the horizontal axis represents time, whereas the vertical axis represents either voltage or current, as appropriate. More specifically, FIG. 4 illustrates an example of changes over time in the current and voltage in the case where the gate drive circuit 34 is placed close to the semiconductor module 10a to reduce the gate wire length. FIG. 5 illustrates an example of changes over time in the current and voltage in the case where the gate wire length between the gate drive circuit 34 and the second control terminal 11d1 of the semiconductor module 10a is set to 30 cm.

FIGS. 4 and 5 each illustrate an example of changes over time in the voltage V_{GE} (10 V/div) between the gate electrode and emitter electrode of the second switching element 14b and the voltage V_{CE} (200 V/div) between the collector electrode and emitter electrode of the second switching element 14b. FIGS. 4 and 5 each also illustrate an example of changes over time in the gate current I_{g} (2 A/div) of the second switching element 14b and the collector current I_{c} (250 A/div) of the second switching element 14b.

A gate inductance component (Lg in FIG. 3) in the case of the short gate wire length is smaller than that in the case of the long gate wire length. Therefore, the rate of increase of the gate current I_{g} in a period of time t1 to t2, during which the second switching element 14b turns on, in the case of the short gate wire length is faster than that in the case of the long gate wire length. At this time, resonance occurs due to the parasitic capacitance of the second switching element 14b and the parasitic inductance component Le between the second auxiliary terminal 11d2 and the emitter electrode of the second switching element 14b. The resonance current generated by this resonance increases as the gate inductance component decreases. It is deduced that, when this resonance current flows from the emitter electrode to the gate electrode, a decrease in the voltage V_{CE} in the period of time t1 to t2 is prevented and the turn-on loss is thus large.

On the other hand, the gate inductance component (Lg in FIG. 3) in the case of the long gate wire length is larger than that in the case of the short gate wire length. Therefore, the rate of increase of the gate current I_{g} in the period of time t1 to t2 in the case of the long gate wire length is slower than that in the case of the short gate wire length. At this time, the above resonance is less likely to occur, and the occurrence of the resonance current is prevented by the gate inductance component Lg. It is therefore deduced that the rate of decrease of the voltage V_{CE} in the period of time t1 to t2 increases and the turn-on loss is thus small.

As described above, the occurrence of resonance is considered a cause of an increase in the turn-on loss. One conceivable approach to suppress the occurrence of resonance is to increase the gate wire length as mentioned above. Alternatively, the occurrence of resonance is suppressed by reducing the parasitic inductance component Le between the second auxiliary terminal 11d2 and the emitter electrode of the second switching element 14b.

The semiconductor module 10 of the first embodiment is designed to reduce the parasitic inductance component Le in order to suppress the occurrence of resonance and to thereby reduce the turn-on loss.

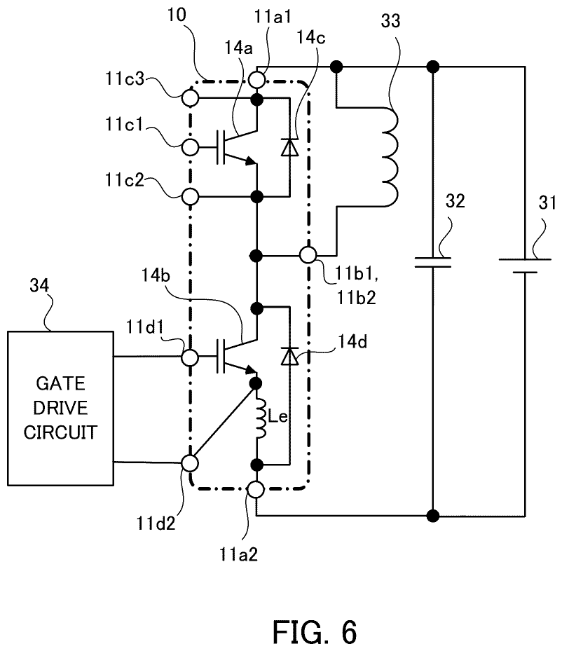

FIG. 6 is a circuit diagram illustrating an example of leading out the second auxiliary terminal in the semiconductor module according to the first embodiment. In FIG. 6, the same reference numerals are given to the same components as in FIGS. 1 to 3.

In the semiconductor module 10 of FIG. 1, one end of the first wiring member 16a connected to the second auxiliary terminal 11d2 is connected to the position 20d on the fifth metal pattern 15b2 that is farther from the first short side portion 11a than the midpoint of the length w of the second insulated circuit substrate 13b in the X direction. Therefore, as illustrated in FIG. 6, the second auxiliary terminal 11d2 is led out from the position that is farther from the second input terminal 11a2 than the position in the semiconductor module 10a illustrated in FIGS. 2 and 3. In other words, the second auxiliary terminal 11d2 is led out from the position that is closer to the emitter electrode of the second switching element 14b.

This configuration reduces the parasitic inductance component Le between the second auxiliary terminal 11d2 and the emitter electrode of the second switching element 14b, compared to the semiconductor module 10a illustrated in FIGS. 2 and 3. As a result, the occurrence of resonance is suppressed, so that the turn-on loss is reduced.

The following presents examples of changes over time in the current and voltage at various locations in the semiconductor module 10 illustrated in FIG. 1 in the case where the position from which the second auxiliary terminal 11d2 is led out is changed.

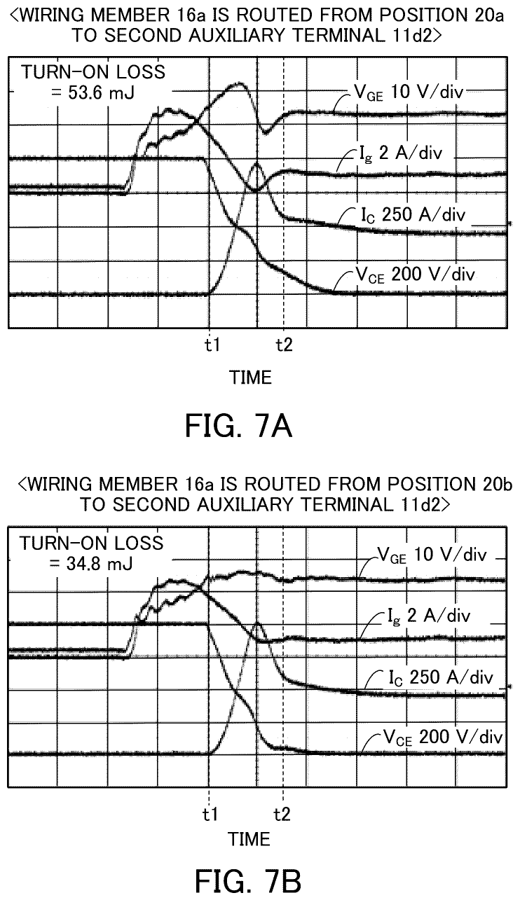

FIGS. 7A and 7B include views each representing changes over time in the current and voltage at various locations in the semiconductor module in the case where the second auxiliary terminal is led out from a position that is closer to the first short side portion than the midpoint of the length of the second insulated circuit substrate in the long-side direction of the terminal case. FIG. 7A relates to the case where the second auxiliary terminal is led out from the position 20a, and FIG. 7B relates to the case where the second auxiliary terminal is led out from the position 20b.

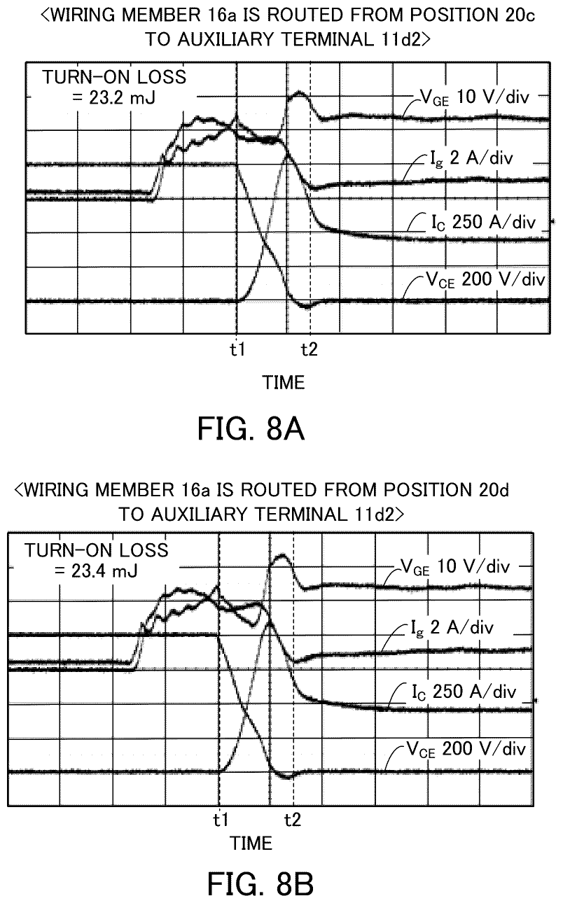

FIGS. 8A and 8B include views each representing changes over time in the current and voltage at the various locations in the semiconductor module in the case where the second auxiliary terminal is led out from a position that is farther from the first short side portion than the midpoint of the length of the second insulated circuit substrate in the long-side direction of the terminal case. FIG. 8A relates to the case where the second auxiliary terminal is led out from the position 20c, and FIG. 8B relates to the case where the second auxiliary terminal is led out from the position 20d.

In FIGS. 7A, 7B, 8A, and 8B, the horizontal axis represents time, whereas the vertical axis represents the magnitude of either voltage or current, as appropriate. FIGS. 7A, 7B, 8A, and 8B illustrate examples of changes over time in the voltage V_{GE} (10 V/div) between the gate electrode and the emitter electrode of each second switching element 14b1 to 14b3 and the voltage V_{CE} (200 V/div) between the collector electrode and the emitter electrode thereof. FIGS. 7A, 7B, 8A, and 8B also illustrate examples of changes over time in the gate current I_{g} (2 A/div) of each second switching element 14b1 to 14b3 and the collector current I_{c} (250 A/div) thereof.

Among the positions 20a to 20d, the position 20a is the closest to the first short side portion 11a. Therefore, in the case of the short gate wire length, a decrease in the voltage V_{CE} in the period of time t1 to t2 is prevented, as in the case illustrated in FIG. 4, etc., so that the turn-on loss increases. In the example illustrated in FIG. 7A, the turn-on loss is 53.6 mJ.

The position 20b is farther in the −X direction from the first short side portion 11a than the position 20a, but is closer to the first short side portion 11a than the midpoint of the length w of the second insulated circuit substrate 13b. Therefore, in the case of the short gate wire length, a decrease in the voltage V_{CE} in the period of time t1 to t2 is prevented, as in the case illustrated in FIG. 4, etc., so that a reduction in the turn-on loss is limited. In the example illustrated in FIG. 7B, the turn-on loss is 34.8 mJ.

The position 20c is farther to the first short side portion 11a than the midpoint of the length w of the second insulated circuit substrate 13b in the X direction. In addition, the position 20c is in the vicinity of the connection areas 21b and 21c that are farther from the first short side portion 11a than the connection area 21a among the above-described connection areas 21a to 21c. In this case, the parasitic inductance component Le between the second auxiliary terminal 11d2 and the emitter electrode of each second switching element 14b1 to 14b3 decreases. Therefore, the occurrence of resonance is suppressed, so that the turn-on loss decreases. In the example illustrated in FIG. 8A, the turn-on loss is 23.2 mJ, meaning that it is reduced to less than half the turn-on loss that occurs in the case where the second auxiliary terminal 11d2 is led out from the position 20a.

The position 20d is farther to the first short side portion 11a than the midpoint of the length w of the second insulated circuit substrate 13b in the X direction. In addition, the position 20d is in the vicinity of the connection area 21c that is the farthest from the first short side portion 11a among the above-described connection areas 21a to 21c. In this case, the parasitic inductance component Le between the second auxiliary terminal 11d2 and the emitter electrode of each second switching element 14b1 to 14b3 also decreases. Therefore, the occurrence of resonance is suppressed, so that the turn-on loss decreases. In the example illustrated in FIG. 8B, the turn-on loss is 23.4 mJ, meaning that it is reduced to the same extent as the case where the second auxiliary terminal 11d2 is led out from the position 20c.

As described above, in the semiconductor module 10 of the first embodiment, the second auxiliary terminal 11d2 is led out from a position that is closer to the emitter electrode of the second switching element 14b1. Since the parasitic inductance component Le decreases, the occurrence of resonance is suppressed, so that the turn-on loss is reduced.

### Second Embodiment

As described above, the occurrence of resonance is considered a cause of an increase in turn-on loss. One conceivable approach to suppress the occurrence of the resonance is to increase the gate wire length as described above. Alternatively, the occurrence of the resonance is suppressed by reducing the parasitic inductance component Le between the second auxiliary terminal 11d2 and the emitter electrode of each second switching element 14b1 to 14b3.

A semiconductor module of the second embodiment is designed to have an increased gate wire length in order to suppress the occurrence of resonance and to thereby reduce the turn-on loss.

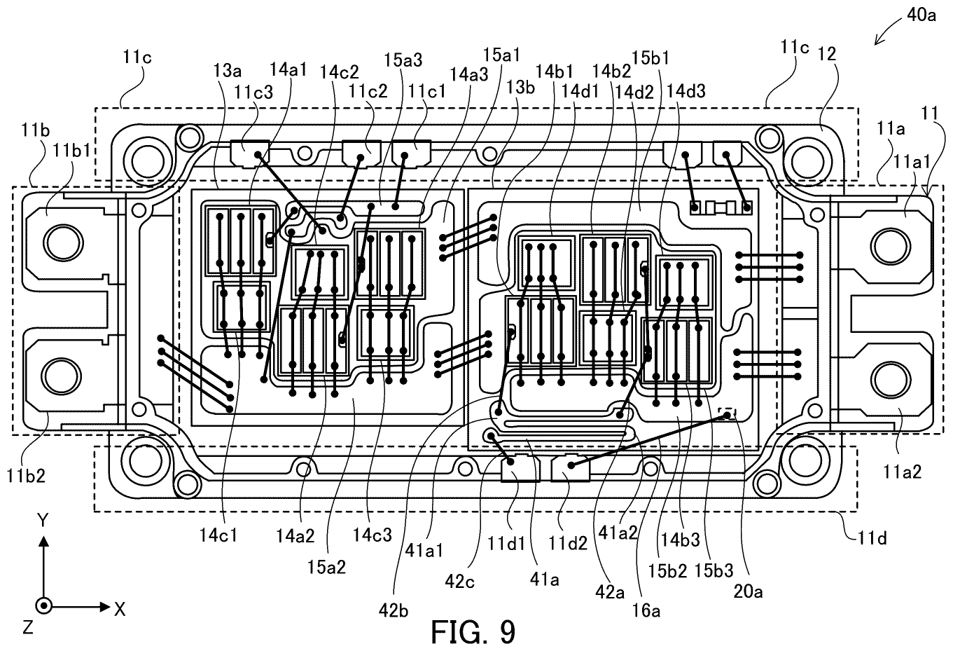

FIG. 9 is a plan view illustrating an example of a semiconductor module according to the second embodiment. In FIG. 9, the same reference numerals are given to the same components as in the semiconductor module 10 of the first embodiment illustrated in FIG. 1.

The semiconductor module 40a of the second embodiment includes a seventh metal pattern 41a that is electrically connected to second control electrodes (the gate electrodes of the second switching elements 14b1 to 14b3) and a second control terminal 11d1, which is different from the seventh metal pattern 15b4 of FIG. 1.

Referring to the example of FIG. 9, the seventh metal pattern 41a includes two turning portions 41a1 and 41a2 that are turned back in the long-side direction (X direction) of a terminal case 11 in plan view. The gate electrodes of the second switching elements 14b2 and 14b3 are electrically connected to one end of the seventh metal pattern 41a via a third wiring member 42a such as a bonding wire. Further, referring to the example of FIG. 9, the gate electrode of the second switching element 14b1 is electrically connected to the turning portion 41a1 via a fourth wiring member 42b such as a bonding wire. Still further, the second control terminal 11d1 is electrically connected to the other end of the seventh metal pattern 41a via a fifth wiring member 42c such as a bonding wire.

Unlike the semiconductor module 10 of the first embodiment, a second auxiliary terminal 11d2 is led out from a position 20a of a fifth metal pattern 15b2. That is, one end of a first wiring member 16a is connected to the position 20a on the fifth metal pattern 15b2 that is closer to the first short side portion 11a than the midpoint (w/2) of the length w of the second insulated circuit substrate 13b in the X direction of the terminal case 11 illustrated in FIG. 1. The other end of the first wiring member 16a is connected to the second auxiliary terminal 11d2.

The semiconductor module 40a having the seventh metal pattern 41a as described above is able to have an increased distance between each position to which the gate electrodes of the second switching elements 14b1 to 14b3 are electrically connected and the position to which the second control terminal 11d1 is electrically connected.

In this connection, the positions on the seventh metal pattern 41a to which the gate electrodes of the second switching elements 14b1 to 14b3 are electrically connected are not limited to those illustrated in FIG. 9.

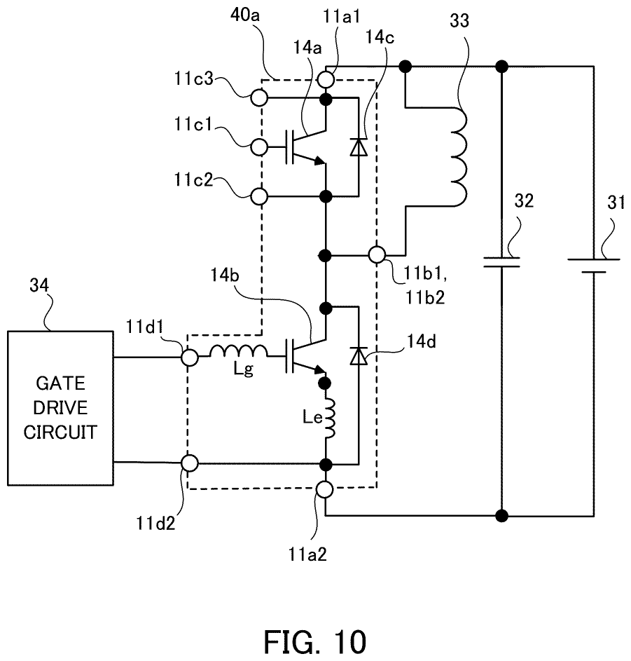

FIG. 10 is a circuit diagram of the semiconductor module according to the second embodiment. In FIG. 10, the same reference numerals are given to the same components as in FIG. 3, etc. In FIG. 3, the gate wire length between the second control terminal 11d1 and the gate drive circuit 34 is increased. In FIG. 10, on the other hand, the seventh metal pattern 41a as illustrated in FIG. 9 is used in the semiconductor module 40a in order to increase the gate wire length.

This semiconductor module 40a is able to increase the gate inductance component (Lg in FIG. 10). As illustrated in FIG. 5 described above, the rate of increase of the gate current I_{g} in the period of time t1 to t2 is slower than that in the case of short gate wire length. At this time, the above-described resonance is less likely to occur, and the occurrence of resonance current is suppressed by the gate inductance component Lg. Therefore, the rate of decrease of the voltage V_{CE} in the period of time t1 to t2 increases, so that the turn-on loss is reduced.

### First Modification

The shape of the seventh metal pattern 41a is not limited to that illustrated in FIG. 9. The seventh metal pattern may include at least one turning portion in plan view.

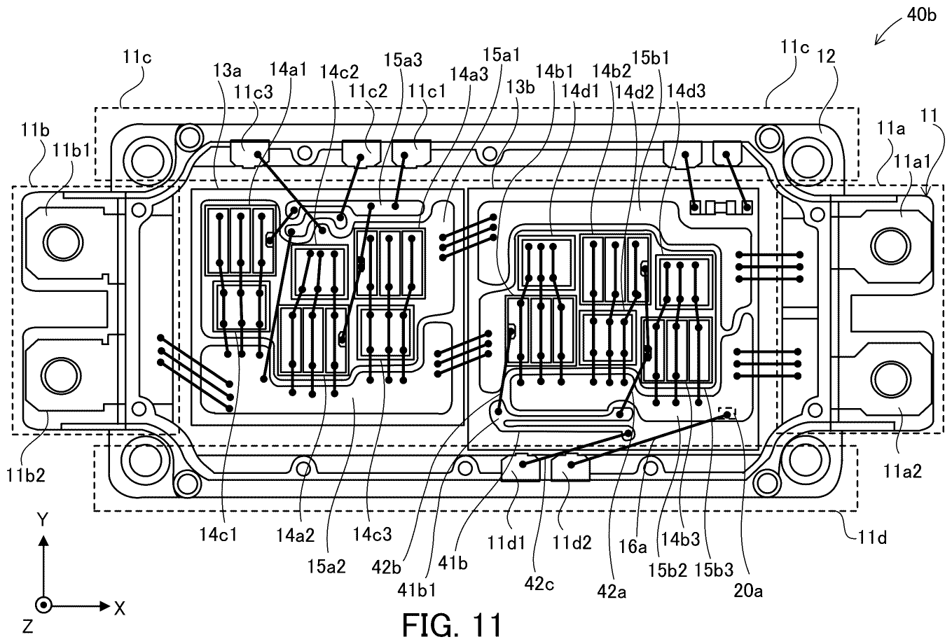

FIG. 11 is a plan view of a semiconductor module according to a first modification of the second embodiment. In FIG. 11, the same reference numerals are given to the same components as in FIG. 10.

Referring to the example of FIG. 11, the seventh metal pattern 41b includes one turning portion 41b1 that is tuned back in the long-side direction (X direction) of a terminal case 11 in plan view. The gate electrodes of second switching elements 14b2 and 14b3 are electrically connected to one end of the seventh metal pattern 41b via a third wiring member 42a such as a bonding wire.

In addition, referring to the example of FIG. 11, the gate electrode of a second switching element 14b1 is electrically connected to the turning portion 41b1 via a fourth wiring member 42b such as a bonding wire. Furthermore, a second control terminal 11d1 is electrically connected to the other end of the seventh metal pattern 41b via a fifth wiring member 42c such as a bonding wire.

The use of the above seventh metal pattern 41b makes it possible to increase the gate wire length and thus to achieve the same effect as the semiconductor module 40a. This semiconductor module 40b may be applicable in the case where the gate wire length does not need to be as long as that of the semiconductor module 40a.

### Second Modification

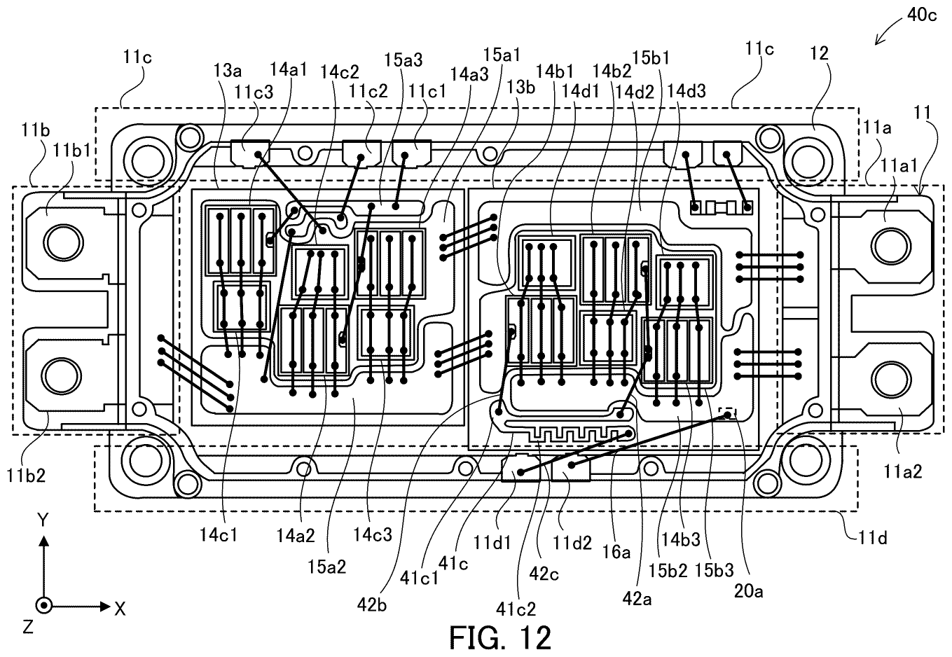

FIG. 12 is a plan view of a semiconductor module according to a second modification of the second embodiment. In FIG. 12, the same reference numerals are given to the same components as in FIGS. 10 and 11.

The semiconductor module 40c illustrated in FIG. 12 includes a seventh metal pattern 41c as described below. The seventh metal pattern 41c includes one turning portion 41c1 that is turned back in the long-side direction (X direction) of a terminal case 11 in plan view, and a plurality of turning portions (e.g., turning portions 41c2) that are turned back in the short-side direction (Y direction) of the terminal case 11. The gate electrodes of second switching elements 14b2 and 14b3 are electrically connected to one end of the seventh metal pattern 41c via a third wiring member 42a such as a bonding wire.

In addition, referring to the example of FIG. 12, the gate electrode of a second switching element 14b1 is electrically connected to the turning portion 41c1 via a fourth wiring member 42b such as a bonding wire. Furthermore, a second control terminal 11d1 is electrically connected to the other end of the seventh metal pattern 41c via a fifth wiring member 42c such as a bonding wire.

The use of the above seventh metal pattern 41c including the turning portions 41c2 turned back in the short-side direction of the terminal case 11 makes it possible to increase the gate wire length and thus to achieve the same effect as the semiconductor module 40a.

### Third Modification

The above has described the semiconductor modules 40a, 40b, and 40c in which the seventh metal patterns 41a, 41b, and 41c each have one or more turning portions in order to increase the gate wire length. Alternatively, to increase the gate wire length, the fifth wiring member 42c may be formed to have a turning portion. As the fifth wiring member 42c, a bonding wire or a lead frame with one or more turning portions may be used, for example. In this connection, the fifth wiring member 42c is an example of the second wiring member disclosed in claim 4.

The above is a description of one aspect of the semiconductor modules based on the embodiments. These are only examples and are not limited to the above description.

The disclosed techniques make it possible to reduce the turn-on loss of a switching element.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor module, comprising:
a terminal case, having:
four side portions, which include a first short side portion and a second short side portion opposite to each other and extending in a first direction, and a first long side portion and a second long side portion opposite to each other and extending in a second direction, the four side portions surrounding a region,
a first input terminal and a second input terminal disposed at the first short side portion,
an output terminal disposed at the second short side portion,
a first control terminal and a first auxiliary terminal disposed at the first long side portion, and
a second control terminal and a second auxiliary terminal disposed at the second long side portion;
a first insulated circuit substrate disposed adjacent to the second short side portion in the region surrounded by the four side portions of the terminal case, the first insulated circuit substrate having, on a front surface thereof,
a plurality of first switching elements each including a first input electrode, a first output electrode, and a first control electrode,
a first metal pattern electrically connected to the first input terminal and the first input electrodes,
a second metal pattern electrically connected to the output terminal, the first output electrodes, and the first auxiliary terminal, and
a third metal pattern electrically connected to the first control electrodes and the first control terminal;
a second insulated circuit substrate disposed adjacent to the first short side portion in the region surrounded by the four side portions of the terminal case, the second insulated circuit substrate having, on a front surface thereof,
a plurality of second switching elements each including a second input electrode, a second output electrode, and a second control electrode,
a fourth metal pattern electrically connected to the first input terminal and the first metal pattern,
a fifth metal pattern electrically connected to the second input terminal, the second output electrodes, and the second auxiliary terminal, the fifth metal pattern extending in the second direction,
a sixth metal pattern electrically connected to the second input electrodes and the second metal pattern, and
a seventh metal pattern electrically connected to the second control electrodes and the second control terminal; and
a first wiring member, having:
a first end connected to the fifth metal pattern at a position that is farther in the second direction from the first short side portion than a midpoint of the second insulated circuit substrate with respect to the second direction, and
a second end connected to the second auxiliary terminal.

2. The semiconductor module according to claim 1, wherein
the plurality of second switching elements are three second switching elements arranged in the second direction,
the fifth metal pattern has three connection areas arranged in the second direction, the three second input electrodes of the three second switching elements being electrically connected respectively to the three connection areas via three second wiring members, two of the three connection areas being farther from the first short side portion than the other connection area of the three connection areas, and
the position at which the first wiring member is connected to the fifth metal pattern is in a vicinity of one of said two connection areas that are farther from the first short side portion.

3. The semiconductor module according to claim 1, wherein
the plurality of second switching elements are three second switching elements arranged in the second direction,
the fifth metal pattern has three connection areas arranged in the second direction, the three second input electrodes of the three second switching elements being electrically connected respectively to the three connection areas via three second wiring members, and
the position at which the first wiring member is connected to the fifth metal pattern is in a vicinity of one of the three connection areas that is farthest from the first short side portion.

4. A semiconductor module, comprising:
a terminal case, having:
four sides portions, which include a first short side portion and a second short side portion opposite to each other and extending in a first direction, and a first long side portion and a second long side portion opposite to each other and extending in a second direction, the four side portions surrounding a region,
a first input terminal and a second input terminal disposed at the first short side portion,
an output terminal disposed at the second short side portion,
a first control terminal and a first auxiliary terminal disposed at the first long side portion, and
a second control terminal and a second auxiliary terminal disposed at the second long side portion;
a first insulated circuit substrate disposed adjacent to the second short side portion in the region surrounded by the four side portions of the terminal case, the first insulated circuit substrate having, on a front surface thereof,
a plurality of first switching elements each including a first input electrode, a first output electrode, and a first control electrode,
a first metal pattern electrically connected to the first input terminal and the first input electrodes,
a second metal pattern electrically connected to the output terminal, the first output electrodes, and the first auxiliary terminal, and
a third metal pattern electrically connected to the first control electrodes and the first control terminal;
a second insulated circuit substrate disposed adjacent to the first short side portion in the region surrounded by the four side portions of the terminal case, the second insulated circuit substrate having, on a front surface thereof,
a plurality of second switching elements each including a second input electrode, a second output electrode, and a second control electrode,
a fourth metal pattern electrically connected to the first input terminal and the first metal pattern,
a fifth metal pattern electrically connected to the second input terminal, the second output electrodes, and the second auxiliary terminal, the fifth metal pattern extending in the second direction,
a sixth metal pattern electrically connected to the second input electrodes and the second metal pattern, and
a seventh metal pattern electrically connected to the second control electrodes and the second control terminal; and
a first wiring member, having:
a first end connected to the fifth metal pattern at a position that is closer in the second direction to the first short side portion than a midpoint of the second insulated circuit substrate with respect to the second direction, and
a second end connected to the second auxiliary terminal,
wherein the seventh metal pattern includes a turning portion in a plan view of the semiconductor module.

5. The semiconductor module according to claim 4, wherein the seventh metal pattern turns in the second direction at the turning portion in the plan view.

6. The semiconductor module according to claim 4, wherein the seventh metal pattern turns in the first direction in the plan view at the turning portion.

7. A semiconductor module, comprising:
a terminal case, having:
four sides portions, which include a first short side portion and a second short side portion opposite to each other and extending in a first direction, and a first long side portion and a second long side portion opposite to each other and extending in a second direction, the four side portions surrounding a region,
a first input terminal and a second input terminal disposed at the first short side portion,
an output terminal disposed at the second short side portion,
a first control terminal and a first auxiliary terminal disposed at the first long side portion, and
a second control terminal and a second auxiliary terminal disposed at the second long side portion;
a first insulated circuit substrate disposed adjacent to the second short side portion in the region surrounded by the four side portions of the terminal case, the first insulated circuit substrate having, on a front surface thereof,
a plurality of first switching elements each including a first input electrode, a first output electrode, and a first control electrode,
a first metal pattern electrically connected to the first input terminal and the first input electrodes,
a second metal pattern electrically connected to the output terminal, the first output electrodes, and the first auxiliary terminal, and
a third metal pattern electrically connected to the first control electrodes and the first control terminal;
a second insulated circuit substrate disposed adjacent to the first short side portion in the region surrounded by the four side portions of the terminal case, the second insulated circuit substrate having, on a front surface thereof,
a plurality of second switching elements each including a second input electrode, a second output electrode, and a second control electrode,
a fourth metal pattern electrically connected to the first input terminal and the first metal pattern,
a fifth metal pattern electrically connected to the second input terminal, the second output electrodes, and the second auxiliary terminal, the fifth metal pattern extending in the second direction,
a sixth metal pattern electrically connected to the second input electrodes and the second metal pattern, and
a seventh metal pattern electrically connected to the second control electrodes and the second control terminal;
a first wiring member, having:
a first end connected to the fifth metal pattern at a position that is closer in the second direction to the first short side portion than a midpoint of the second insulated circuit substrate with respect to the second direction, and
a second end connected to the second auxiliary terminal; and
a second wiring member electrically connecting the seventh metal pattern to the second control terminal, the second wiring member including at least one turning portion in a plan view of the semiconductor module.
